(19) United States
(12) Patent Application Publication
(10) Pub. No.: US 2005/0014359 A1
(43) Pub. Date: Jan. 20, 2005

(54) Semiconductor device manufacturing method

(76) Inventors: Yuji Segawa, Tokyo (JP); Takeshi Nogami, Kanagawa (JP); Hiroshi Horikoshi, Kanagawa (JP); Naoki Komai, Kanagawa (JP)

Correspondence Address: Ronald P Kananen;Rader Fishman & Grauer, The Lion Building Suite 501, 1233 20th Street NW, Washington, DC, 20036, US

(21) Appl. No.: 10/486,446

(22) PCT Filed: Jun. 20, 2003
(86) PCT No.: PCT/JP03/07871

(30) Foreign Application Priority Data
Jun. 25, 2002 (JP) 20021-84873

(51) Int. Cl. H01L 21/4763; H01L 21/44

(52) U.S. Cl. 438/622; 438/643; 438/687; 438/678

(57) ABSTRACT

A method of manufacturing a semiconductor device for realizing a semiconductor device which is suitable for enhancing the operating speed thereof and which is high in quality and reliability is provided.

The method of manufacturing a semiconductor device is a method of manufacturing a semiconductor device including a barrier film (7) having a copper diffusion preventive function and formed on a copper-containing metallic wire (9), the method including the steps of: conducting electroplating by use of an electroplating liquid containing a catalyst metal (10) added thereto so as thereby to form the metallic wiring (2) containing the catalyst metal (10); and conducting electroless plating by use of the catalyst metal (10) exposed at the surface of the metallic wiring (2) as a catalyst so as thereby to form the barrier film (7) having the copper diffusion preventive function on the metallic wiring (2).

### TECHNICAL FIELD

The present invention relates to a method of manufacturing a semiconductor device including a metallic wiring containing copper, and particularly to a method of manufacturing a semiconductor device in which diffusion of copper into an inter-layer insulating film or the like is prevented.

### BACKGROUND ART

Conventionally, aluminum-based alloys are used as a material of a minute wiring of a high-density integrated circuit formed on a semiconductor wafer. For enhancing the operating speed of a semiconductor device, however, it is necessary to use a material lower in resistivity than aluminum-based alloys as the wiring material, and copper, silver and the like are preferable for use as such a low-resistivity material. Particularly, copper is expected as a next-generation material because it has a low resistivity of 1.8 μΩcm, it is therefore advantageous for enhancing the operating speed of a semiconductor device, and it is higher in electro-migration resistance than aluminum-based alloys by about one order.

In formation of a wiring by use of copper, generally, the so-called Damascene process is used because dry etching of copper is difficult to carry out. The process includes the steps of preliminarily forming a groove in an inter-layer insulating film formed, for example, of silicon oxide, filling the groove with a wiring material (copper), and removing the excess wiring material by chemical mechanical polishing (hereinafter referred to as CMP), thereby forming a wiring. Further, there has been known the dual Damascene process including the steps of forming connection holes (via holes) and a wiring groove (trench), then collectively filling these with a wiring material, and removing the excess wiring material by CMP.

Meanwhile, the copper wiring is generally used in the form of a multi-layer structure. In this case, for the purpose of preventing the diffusion of copper into the inter-layer insulating film, a barrier film consisting of silicon nitride, silicon carbide or the like is formed before the formation of the wiring.

However, since the barrier film is absent on the surface of the copper wiring immediately after the CMP, the barrier film for functioning as a copper diffusion preventive layer is formed before the formation of the upper-layer wiring. In this case, since copper is easily oxidized in an oxygen-containing atmosphere even at a low temperature of around 150° C., a silicon nitride film (SiN) a silicon carbide film (SiC) or the like is ordinarily used as the barrier layer.

It should be noted here that silicon nitride (SiN) and silicon carbide (SiC) are higher in relative dielectric constant than silicon oxide (SiO₂), which leads to the problems that the effective dielectric constant of the semiconductor device including the copper wiring will be high, the semiconductor will be high in RC delay (delay of the wiring due to resistance and capacitance), and the electro-migration resistance at the interface between the SiN or SiC constituting the barrier film and copper will be weak.

In view of the above problems, formation of a film of CoWP on the surface of the copper wiring after the CMP as a material which is excellent in prevention of copper diffusion, improvement of RC delay, and electro-migration resistance has been proposed by U.S. Pat. No. 5,695,810 (USE OF COBALT TUNGSTEN PHOSPHITE AS A BARRIER MATERIAL FOR COPPER METALLIZATION). Furthermore, CoWP has the characteristic feature that a film thereof can be selectively formed only on the copper wiring by electroless plating.

A conventional semiconductor device using CoWP as the barrier film is shown in FIG. 21. The semiconductor device includes a copper-containing metallic wiring, on which is formed a barrier film composed of CoWP and having a copper diffusion preventive function. The semiconductor device has a constitution in which lower-layer wirings 102a and 102b as the copper-containing metallic wirings (hereinafter referred to as Cu wirings) are used to fill grooves provided in an insulating layer 103a, on a substrate 101 preliminarily provided with devices (not shown) such as transistors. The insulating layer 103a is formed, for example, of SiOC, and a barrier metal film 104a formed, for example, of TaN is formed between the lower-layer wirings 102a, 102b and the insulating layer 103a. In addition, an etch stopper layer 105 formed of SiC, for example, is formed between the substrate 101 and the insulating layer 103a, for preventing the diffusion of Cu from the lower-layer wirings 102a and 102b into the substrate 101. Besides, an insulating film 103b is provided on the lower-layer wirings 102a and 102b and the insulating layer 103a, with an SiN film for copper diffusion prevention therebetween. The insulating film 103b is formed of SiO₂, for example.

Furthermore, an insulating film 103c is formed on the insulating film 103b, with an SiN film for copper diffusion prevention therebetween, and upper-layer wirings 106a and 106b as copper-containing metallic wirings are formed in grooves provided in the insulating layer 103b and the insulating layer 103c, with a barrier metal film 104b consisting, for example, of TaN therebetween. A barrier film 108 consisting of CoWP and having a copper diffusion preventing function is formed on the upper-layer wirings 106a and 106b, i.e., on the surfaces not covered with the barrier metal film 104b, i.e., the top surfaces in FIG. 21, of the upper-layer wirings 106a and 106b, with a palladium (Pd) replacement layer 107 therebetween.

To manufacture the above-mentioned semiconductor device, electroless plating with CoWP is applied onto the copper wiring, to form the barrier layer. Now, the method and principle of forming a film of CoWP on the copper wiring by electroless plating will be described in brief. In order to selectively forming the film of CoWP on the copper wiring by the electroless plating method, a catalyst layer for starting electroless plating is needed. Copper is low in catalytic activity, and, therefore, it does not function as a sufficient catalyst for deposition of CoWP. In general, therefore, a method in which a catalytic metal layer of palladium (Pd) or the like is preliminarily formed on the copper surface by replacement plating.

The replacement plating utilizes the differences in ionization tendency between different metals. Since Cu is electrochemically baser than Pd, when Cu is immersed in an HCl solution of PdCl₂, for example, electrons librated attendant on the dissolution of Cu are transferred onto the ions of Pd which is a noble metal in the solution, resulting in the formation of a film of Pd on the surface of Cu which is the baser metal. Since the Pd replacement does not occur on the surfaces of insulating films which necessarily are not metallic, the catalytically active layer is formed only on Cu. Subsequently, an electroless plating reaction starts only on the Cu wiring, with the Pd layer as a catalyst, resulting in the formation of a barrier metal layer formed of CoWP.

The above-mentioned method, however, has the problem that the Cu wiring is damaged by etching when the catalytically active layer is formed on the Cu surface by the Pd replacement plating. Particularly, holes are locally formed in Cu along Cu grains, and, where etching is vigorous, the Cu wiring may be damaged to such an extent as to cause line breakage. As a result, the resistance of the Cu wiring is raised by as much as 30%, for example, where the Cu wiring is severely damaged. Furthermore, it is difficult to fill the holes, generated between the Cu grains, by the formation of the CoWP film. As a result, even after the formation of the CoWP, voids would be left in the Cu wiring, and the electro-migration resistance would be rapidly worsened starting from the voids.

The present invention has been devised in consideration of the above-mentioned circumstances of the prior art. Accordingly, it is an object of the present invention to provide a method of manufacturing a semiconductor device for realizing a semiconductor device which is suitable for enhancing the operating speed thereof and is high in quality and reliability.

### DISCLOSURE OF INVENTION

In order to attain the above object, according to the present invention, there is provided a method of manufacturing a semiconductor device including a barrier film having a copper diffusion preventive function and formed on a metallic wiring, the method including the steps of: conducting electroplating by use of an electroplating liquid containing a catalyst metal added thereto so as thereby to form a metallic wiring containing the catalyst metal; and conducting electroless plating by use of the catalyst metal exposed at the surface of the metallic wiring as a catalyst so as thereby to form the barrier film having the copper diffusion preventive function on the metallic wiring.

Conventionally, in order to form a barrier film on a copper-containing metallic wire by an electroless plating method, it has been necessary to subject the surface of the metallic wiring layer to a catalytically activating treatment using Pd or the like which is a highly catalytic metal. Specifically, it is necessary, for example, to subject the surface of the copper-containing metallic wiring to Pd replacement plating, thereby replacing copper by Pd to form a catalytically active layer, and thereafter to conduct electroless plating by using Pd in the catalytically active layer as nuclei of catalyst.

In the method of manufacturing a semiconductor device according to the present invention, however, in forming the copper-containing metallic wiring, the catalyst metal is preliminarily contained in the metallic wiring, and electroless plating is conducted using the catalyst metal exposed at the surface of the metallic wiring, of the catalyst metal contained in the metallic wiring, as nuclei of catalyst to thereby form the barrier film having the copper diffusion preventive function on the metallic wiring.

To be more specific, in the method of manufacturing a semiconductor device according to the present invention, the catalyst metal is preliminarily added to the electroplating liquid for electroplating, in forming the copper-containing metallic wiring by electroplating. The catalyst metal functions as a catalyst for starting an electroless plating reaction, in forming the barrier film. Then, electroplating is conducted using the electroplating liquid containing the catalyst metal added thereto, whereby the metallic wiring containing the catalyst metal can be formed. That is, it is possible to form a metallic wiring in which the catalyst metal is dispersed inside the metallic wiring and at the surface of the metallic wiring.

Then, removal of unrequired portions and a planarizing treatment are conducted as required, and electroless plating for forming the barrier film by using as a catalyst the catalyst metal exposed at the surface of the metallic wiring, upon which an electroless plating reaction begins with the catalyst metal as a catalyst, and the electroless plating reaction continues due to an autocatalytic action, whereby the barrier film is formed on the metallic wiring.

Here, the catalyst metal is exposed only at the surface of the metallic wiring, and the electroless plating proceeds only where the catalyst metal is present. Therefore, the barrier film can be selectively formed only on the metallic wiring.

In the above-described method, the metallic wiring is formed by the electroplating using the electroplating liquid containing the catalyst metal preliminarily added thereto, whereby the catalyst metal for functioning as the catalyst in electroless plating is dispersed inside the metallic wiring and at the surface of the metallic wiring. This makes it possible to obtain the same effect as that in the case of applying the catalytically activating treatment in the conventional manufacturing method.

In the present invention, therefore, the catalytically activating treatment step indispensable to the conventional manufacturing method is unnecessitated, the barrier film can be efficiently formed by simplified manufacturing steps, and it is possible to manufacture at low cost a high-quality semiconductor device in which diffusion of copper atoms into an inter-layer insulating film is securely prevented.

Besides, in the method of manufacturing a semiconductor device according to the present invention, the metallic wiring itself will not be etched because the catalytically activating step is not conducted, as described above. Specifically, the metallic wiring is free of generation of holes in the metallic wiring due to etching, and is free of damages due to etching, such as generation of line breakage. Therefore, it is possible to manufacture a high-quality semiconductor device while obviating the problems which might cause malfunctions of the semiconductor device, such as a rise in the wiring resistance and a worsening of electro-migration resistance, arising from etching of the metallic wiring.

Furthermore, in the method of manufacturing a semiconductor device according to the present invention, the catalytically activating step is not carried out, and, therefore, the adsorption or remaining of the catalyst metal onto the inter-layer insulating film as in the conventional manufacturing method is obviated. As a result, the barrier film is not formed on the inter-layer insulating film, and, therefore, it is possible to enhance the selectivity of film formation at the time of forming the barrier film and to manufacture a high-quality semiconductor device.

### BRIEF DESCRIPTION OF DRAWINGS

FIG. 1 is a vertical sectional view showing one example of the configuration of a semiconductor device produced by applying the present invention.

FIG. 2 is a vertical sectional view for illustrating the method of manufacturing a semiconductor device according to the present invention.

FIG. 3 is a vertical sectional view for illustrating the method of manufacturing a semiconductor device according to the present invention.

FIG. 4 is a vertical sectional view for illustrating the method of manufacturing a semiconductor device according to the present invention.

FIG. 5 is a vertical sectional view for illustrating the method of manufacturing a semiconductor device according to the present invention.

FIG. 6 is a vertical sectional view for illustrating the method of manufacturing a semiconductor device according to the present invention.

FIG. 7 is a vertical sectional view for illustrating the method of manufacturing a semiconductor device according to the present invention.

FIG. 8 is a vertical sectional view for illustrating the method of manufacturing a semiconductor device according to the present invention.

FIG. 9 is a vertical sectional view for illustrating the method of manufacturing a semiconductor device according to the present invention.

FIG. 10 is a vertical sectional view for illustrating the method of manufacturing a semiconductor device according to the present invention.

FIG. 11 is a vertical sectional view showing the condition where a lower-layer wiring has been formed by applying the present invention.

FIG. 12 is a vertical sectional view for illustrating the method of manufacturing a semiconductor device in the case where the present invention is applied to the dual Damascene process.

FIG. 13 is a vertical sectional view for illustrating the method of manufacturing a semiconductor device in the case where the present invention is applied to the dual Damascene process.

FIG. 14 is a vertical sectional view for illustrating the method of manufacturing a semiconductor device in the case where the present invention is applied to the dual Damascene process.

FIG. 15 is a vertical sectional view for illustrating the method of manufacturing a semiconductor device in the case where the present invention is applied to the dual Damascene process.

FIG. 16 is a vertical sectional view for illustrating the method of manufacturing a semiconductor device in the case where the present invention is applied to the dual Damascene process.

FIG. 17 is a vertical sectional view for illustrating the method of manufacturing a semiconductor device in the case where the present invention is applied to the dual Damascene process.

FIG. 18 is a vertical sectional view for illustrating the method of manufacturing a semiconductor device in the case where the present invention is applied to the dual Damascene process.

FIG. 19 is a vertical sectional view for illustrating the method of manufacturing a semiconductor device in the case where the present invention is applied to the dual Damascene process.

FIG. 20 is a vertical sectional view for illustrating the method of manufacturing a semiconductor device in the case where the present invention is applied to the dual Damascene process.

FIG. 21 is a vertical sectional view showing one example of the configuration of a semiconductor device according to the related art.

### BEST MODE FOR CARRYING OUT THE INVENTION

Now, the method of manufacturing a semiconductor device according to the present invention will be described in detail below referring to the drawings. The present invention is not limited to the following description, and various modifications are possible within the gist of the invention. First, the case where the present invention is applied to a monolayer wiring will be described. In the following drawings, the contraction scale may differ from the actual one, for convenience of description.

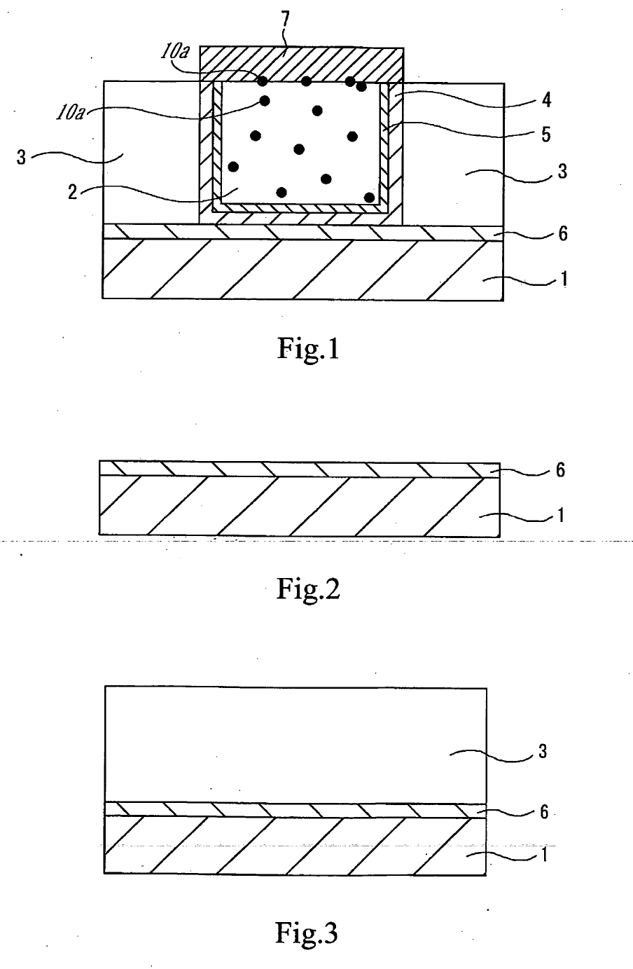

FIG. 1 is a sectional view of an essential part of a semiconductor device produced by applying the present invention. The semiconductor device includes a copper-containing metallic wire, on which is formed a barrier film having a copper diffusion preventive function. The semiconductor device has a configuration in which the copper-containing metallic wire (hereinafter referred to as Cu wiring) 2 is filling a groove provided in an inter-layer insulating film 3, on a substrate 1 preliminarily provided with devices (not shown) such as transistors.

The inter-layer insulating film 3 is composed, for example, of SiOC, SiO₂, SiLK, FLARE, a fluorine-added silicon oxide film (FSG) or other low-dielectric-constant insulating film. Between the Cu wiring 2 and the inter-layer insulating film 3 are formed a barrier metal film 4 having a copper diffusion preventive function, and a Cu seed layer 5 which is to be a conductive layer in forming a film of Cu by electroplating in a Cu filling step. The barrier metal film 4 is composed, for example, of TaN, Ta, Ti, TiN, W, WXN, or a laminated film thereof.

In addition, between the substrate 1 and the inter-layer insulating film 3 is formed an etch stopper layer 6 composed, for example, SiN, SiC, or the like.

Besides, in the semiconductor device, a barrier film 7 having a copper diffusion preventive function is formed on the Cu wiring 2, i.e., on that surface of the Cu wiring 2 which is not covered with the barrier metal film 4, i.e., on the top surface in FIG. 1. Here, the barrier film 7 is constituted of cobalt tungsten phosphite (CoWP) film formed on the Cu wiring. With the barrier film 7 constituted of cobalt tungsten phosphite (CoWP), in the semiconductor device, the barrier film 7 consisting of cobalt tungsten phosphite (CoWP) functions sufficiently as a copper diffusion preventive film, whereby diffusion of copper into the inter-layer insulating film is securely prevented.

In addition, with the barrier film 7 constituted of cobalt tungsten phosphite (CoWP), in the semiconductor device, the problem that electro-migration resistance is weak at the interface between the copper diffusion preventive film and copper and the problem that RC delay is large due to the high dielectric constant of the copper diffusion preventive film itself, which would occur where SiN or the like is used as the material of the barrier film 7, namely, the copper diffusion preventive film, are obviated. Namely, by using a film of cobalt tungsten phosphite (CoWP) as the barrier film 7, there is realized a semiconductor device which is excellent in copper diffusion preventive property, which has an excellent electro-migration resistance and in which RC delay is suppressed.

The semiconductor device as above can be produced as follows. First, as shown in FIG. 2, a material such as SiC and SiN is deposited on the substrate 1 by a CVD (Chemical Vapor Deposition) process, to form the etch stopper layer 6. Specifically, for example, a CVD process is conducted using a mixture gas of monosilane (SiH₄), NH₃ and N₂ as a source gas, to form a film of SiN in a film thickness of 50 nm.

Next, as shown in FIG. 3, in continuation with the formation of the etch stopper layer 6, the inter-layer insulating film 3 consisting of SiO₂ is formed on the whole surface of the etch stopper layer 6 by a CVD process using, for example, a mixture gas of tetraethoxysilane (TEOS) and O₂ as a raw material gas. The formation of the inter-layer insulating film 3 can be conducted in continuity with the formation of the etch stopper 6 in the preceding step in the same chamber. Besides, the material of the inter-layer insulating film 3 is not limited to SiO₂ but may be a known oxide such as SiOC or may be an organic material such as a low-dielectric-constant material.

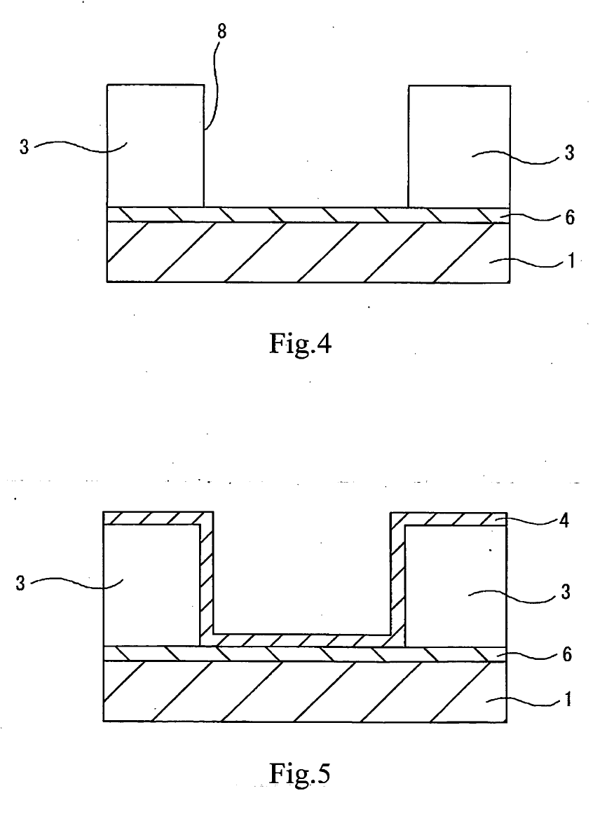

Subsequently, as shown in FIG. 4, a groove 8 for forming a wiring is patterned in the inter-layer insulating film 3 by photolithography and dry etching. For example, the etching of the inter-layer insulating film 3 can be carried out under the following etching conditions.

<Etching Conditions for Inter-layer Insulating Film 3>

| | |
|---|---|
| Gas used: | CHF₃/CF₄/Ar = 30/60/800 sccm |
| Pressure: | 200 Pa |
| Substrate temperature: | 25° C. |

Next, as shown in FIG. 5, the barrier metal film 4 consisting, for example, TaN for preventing the diffusion of Cu into the inter-layer insulating film 3 is formed by a PVD (Physical Vapor Deposition) process. The material of the barrier metal film 4 is not limited to TaN; a material excellent in barrier property against Cu, such as Ta, Ti, TiN, W, WN, or a laminated film thereof and the like can be used as the material of the barrier metal film 4.

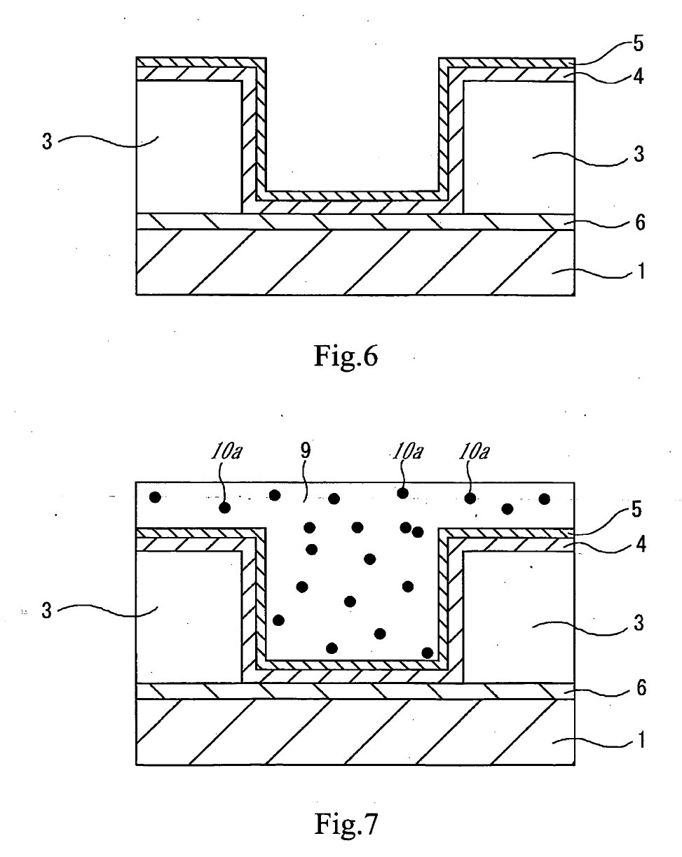

Subsequently, as shown in FIG. 6, the Cu seed layer 5 is formed on the barrier metal film 4 by a PVD process. The Cu seed layer 5 is to be a conductive layer in forming a film of Cu by electroplating in the subsequent Cu filling step. The formation of the barrier metal film 4 and the Cu seed layer 5 may not necessarily be conducted by the PVD process but may be conducted by a CVD process.

The film thicknesses depend on design rules. It is preferable, however, that the film thickness of the barrier metal film 4 is not more than 50 nm, and the film thickness of the Cu seed layer 5 is not more than 200 nm. Therefore, the barrier metal film 4 consisting of TaN, for example, may be formed in a film thickness of 20 nm, and the Cu seed layer 5 may be formed on the barrier metal film 4 in a film thickness of 150 nm. One example of a set of PVD film formation conditions for the barrier metal film 4 in this instance is given below.

<PVD Film Formation Conditions for Barrier Metal Film 4>

| | |
|---|---|
| DC power: | 1 kW |
| Process gas: | Ar = 50 sccm |
| AC wafer bias power: | 350 W |

Besides, one example of a set of PVD film formation conditions for the Cu seed layer 5 is given below.

<PVD Film Formation Conditions for Cu Seed Layer 5>

| | |
|---|---|
| DC power: | 12 kW |
| Pressure: | 0.2 Pa |
| Film formation temperature: | 100° C. |

Next, as shown in FIG. 7, a film of Cu 9 is formed by Cu electroplating, to fill the groove 8 with Cu 9. In this case, Pd as a catalyst metal 10a is preliminarily added to a Cu electroplating liquid for use in Cu electroplating. The catalyst metal 10a is to be a catalyst for starting an electroless plating reaction in forming the barrier film 7 which will be described later. Then, the film of Cu 9 is formed by Cu electroplating using the Cu electroplating liquid containing the catalyst metal 10a such as Pd added thereto, in the manner of filling the groove 8 with Cu 9, whereby the Cu wiring 2 containing the catalyst metal 10a can be formed. Specifically, it is possible to form the Cu wiring 2 such that the catalyst metal 10a is dispersed at random inside the Cu wiring 2 and at the surface of the Cu wiring 2.

In the conventional method of manufacturing a semiconductor device, in order to form the barrier film 7 on the Cu wiring 2, the surface of the Cu wiring 2 must be subjected to a catalytically activating treatment using Pd or the like which is a highly catalytic metal. Specifically, it is necessary, for example, to replace the surface of the Cu wiring 2 with Pd by Pd replacement plating, thereby forming a catalytically active layer on the surface of the Cu wiring 2, and then to conducting electroless plating by use of Pd of the catalytically active layer as nuclei of catalyst.

On the other hand, in the method of manufacturing a semiconductor device according to the present invention, the Cu wiring 2 containing the catalyst metal 10a can be formed by conducting Cu electroplating while using the Cu electroplating liquid containing the catalyst metal 10a preliminarily added thereto, as described above. Namely, the catalyst metal 10a as a catalyst for starting an electroless plating reaction can be dispersed inside the Cu wiring 2 and at the surface of the Cu wiring 2.

This makes it possible to obtain the same effect as that in the case of applying the catalytically activating treatment in the conventional manufacturing method, so that the catalytically activating treatment indispensable to the conventional manufacturing method is unnecessitated. In the method of manufacturing a semiconductor device according to the present invention, therefore, it is possible to efficiently form the barrier film 7 by simplified manufacturing steps, and to manufacture at low cost a high-quality semiconductor device in which the diffusion of copper atoms into the inter-layer insulating film is securely prevented.

Besides, in the method of manufacturing a semiconductor device according to the present invention, the Cu wiring 2 is not etched at the time of forming the barrier layer 7, since the catalytically activating step is not performed. In addition, in the method of manufacturing a semiconductor device according to the present invention, the absence of the catalytically activating step ensures that the Cu wiring 2 is free of generation of holes in the Cu wiring 2 by etching and is free of damage due to etching, such as generation of line breakage. Therefore, a rise in wiring resistance, a worsening of electro-migration resistance, and the like, due to etching of the Cu wiring 2, are obviated. Accordingly, it is possible to manufacture a high-quality semiconductor device in which malfunctions of the semiconductor device due to etching of the Cu wiring 2 will not occur.

In the method of manufacturing a semiconductor device according to the present invention, furthermore, the catalytically activating step is not carried out, and, therefore, the adsorption or remaining of the catalyst metal onto the inter-layer insulating film 3, as seen in the conventional manufacturing method, is obviated. As a result, formation of the barrier layer 7 on the inter-layer insulating film 3 is obviated, making it possible to enhance the selectivity of film formation in forming the barrier film 7 which will be described later. This is because electroless plating proceeds only where the catalyst metal 10 is present, and the catalyst metal 10a is selectively disposed only on the Cu wiring 2 in the method of manufacturing a semiconductor device according to the present invention.

In addition, since a copper sulfate-based electroplating liquid is generally used for Cu electroplating, where Pd, for example is used as the catalyst metal, the method for adding the catalyst metal above-mentioned preferably consists in adding palladium sulfate to the Cu electroplating liquid. In the case where palladium sulfate is simply added to the Cu electroplating liquid, however, hydroxide of Pd is produced by hydrolysis in the Cu electroplating liquid, and the hydroxide migrates in the Cu electroplating liquid, leading to discoloration of the plating liquid and rendering the electroplating instable.

In view of this problem, in the present invention it is preferable to add the catalyst metal in a complexed form to the Cu electroplating liquid. Specifically, in the case where Pd, for example, is added as the catalyst metal, Pd is preferably complexed with citric acid or the like, before being added to the Cu electroplating liquid. With the thus complexed Pd added to the Cu electroplating liquid, generation of hydroxide of Pd due to hydrolysis in the Cu electroplating liquid is obviated, so that there is no possibility of migration of the hydroxide in the Cu electroplating. Therefore, discoloration of the plating liquid and instability of electroplating, due to the hydroxide of Pd, are prevented, and it is possible to achieve a stable high-quality Cu electroplating.

In addition, the catalyst metal to be added to the Cu electroplating liquid is not limited to Pd; gold (Au), platinum (Pt), silver (Ag), rhodium (Rh), cobalt (Co), nickel (Ni) and the like can be used as the catalyst metal. Also in the case of adding any of these metals as the catalyst metal to the Cu electroplating liquid, it is preferable to complex the metal with an appropriate complexing agent such as citric acid, tartaric acid and succinic acid so as to form a metallic salt, before adding it to the Cu electroplating liquid.

Besides, the amount of the catalyst metal, or the dispersion density of that catalyst metal per unit area which is present at the surface of the Cu wiring 2, necessary for starting the electroless plating described later differs depending on the material of the barrier film 7 to be formed. Therefore, the amount of the catalyst metal 10a to be added to the Cu electroplating liquid is not particularly limited, and may be appropriately set according to the material of the barrier film 7 to be formed.

One example of the composition of the Cu electroplating liquid containing the complexed Pd added thereto and one example of a set of Cu electroplating conditions are given below.

<Composition of Cu Electroplating Liquid>

| | |
|---|---|
| Copper sulfate: | 200 g/l to 250 g/l |
| Palladium sulfate: | 10 mg/l to 1 g/l |
| Ammonium citrate: | 20 mg/l to 4 g/l (sodium citrate or the |
| | like may also be used) |
| Sulfuric acid: | 10 g/l to 50 g/l |
| Chloride ion: | 20 mg/l to 80 mg/l |
| Additive such as brightener: | appropriate amount |

<Cu Electroplating Conditions>

| | |
|---|---|
| Plating: | 2.83 A |
| Plating time: | 4 min 30 sec (1 μm) |
| Plating liquid temperature: | 25° C. to 30° C. |
| Cathode current density: | 1 mA/cm² to 5 mA/cm² |

In addition, while the Cu electroplating has been described as conducted in a copper sulfate bath in the foregoing, the Cu electroplating may be conducted by use of a copper borofluoride bath, a copper pyrophosphate bath, a copper cyanide bath or the like.

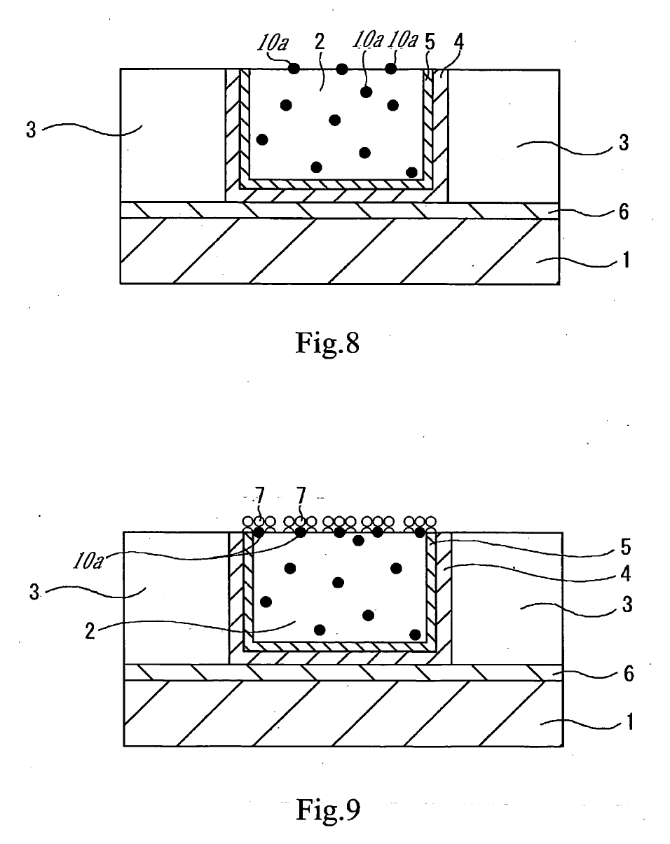

Next, as shown in FIG. 8, surplus portions of Cu 9, the barrier metal film 4 and the Cu seed layer 5 are removed, to leave Cu 9 only in the groove 8, thereby forming the Cu wiring 2. As a result, Pd contained in the Cu wiring 2 is exposed at the surface of the Cu wiring 2. That is, the catalyst metal 10a for functioning as a catalyst in the formation of the barrier film 7 by electroless plating in the subsequent step is exposed at the surface of the Cu wiring 2.

Here, the technology generally applied to the removal of a surplus portion of Cu 9 is polishing by CMP. In this step, it is necessary to finish the polishing at the surface of the inter-layer insulating film 3 so as to leave the wiring material only in the groove 8, and, further, it is preferable to control the polishing so that the wiring material will not be left on the inter-layer insulating film 3. In the step of polishing by CMP, the plurality of materials of Cu 9, the barrier metal 4 and the Cu seed layer 5 must be polished away, and it is therefore necessary to control the polishing liquid (slurry), the polishing conditions and the like according to the materials to be polished. For this purpose, a plurality of polishing steps may be required in some cases. One example of a set of CMP conditions for the surplus Cu is given below.

<CMP Conditions for Cu>

| | |
|---|---|
| Polishing pressure: | 100 g/cm² |
| Rotating speed: | 30 rpm |
| Rotary pad: | laminate of nonwoven fabric and closed-cell foam |
| Slurry: | H₂O₂ added (alumina-containing slurry) |
| Flow rate: | 100 cc/min |
| Temperature: | 25 to 30° C. |

Next, the barrier film 7 is formed on the Cu wiring 2. In this case, if required, a pretreatment for removing a spontaneous oxide film formed on the Cu wiring 2 after the polishing step by CMP is applied, and thereafter the barrier film 7 is formed on the Cu wiring 2 as shown in FIG. 8 by an electroless plating process. With the electroless plating process adopted, the barrier 7 can be selectively formed only on the Cu wiring 2, whereby a step of etching the barrier film 7 can be omitted. One specific example of the pretreatment process is given below.

<Pretreatment>

(1) Degreasing treatment: The wettability of the surface is enhanced by alkali degreasing or acid degreasing.

(2) Acid treatment: Neutralization with 2 to 3% hydrochloric acid or the like is conducted and, simultaneously oxidized Cu at the surface is removed.

(3) Rinsing with Pure Water

In the above pretreatment, examples of the treating methods in (1) degreasing treatment, and (2) acid treatment include a spin treatment by use of a spin coater, a paddle treatment (liquid paddling), and a dipping treatment.

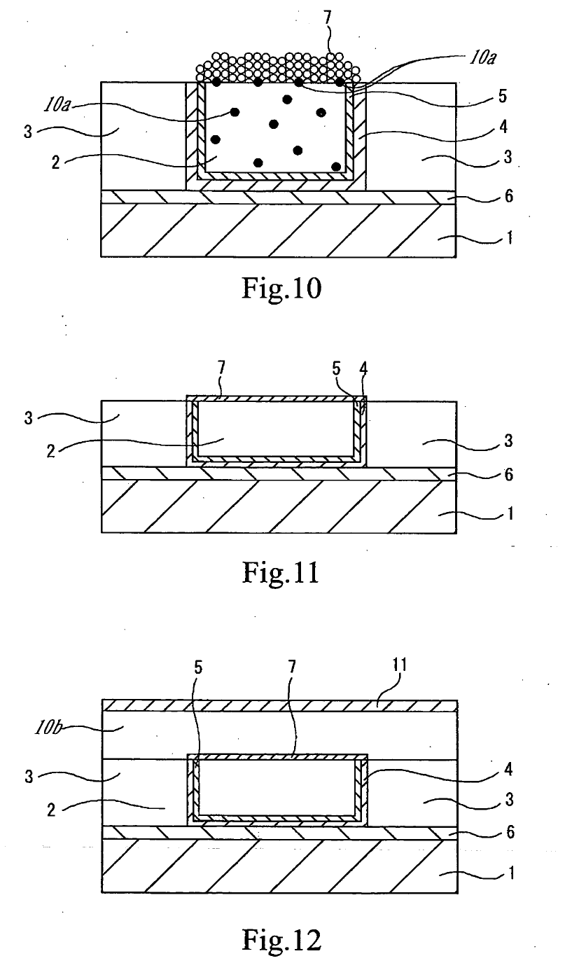

Next, a CoWP film, for example, is formed as the barrier film 7 on the surface of the Cu wiring 2 by electroless plating. To form the CoWP film, as shown in FIG. 9, a CoWP electroless plating reaction is started by using Pd, which is the catalyst metal 10a, exposed at the surface of the Cu wiring 2 as a catalyst. Then, the electroless plating reaction is continued under an autocatalytic action, whereby the CoWP film can be formed on the Cu wiring 2 as shown in FIG. 10.

Here, as described above, Pd being the catalyst metal 10a is exposed only at the surface of the Cu wiring 2, and the electroless plating proceeds only where Pd is present. Therefore, the barrier 7 can be selectively formed only on the Cu wiring 2.

In addition, the barrier film 7 is not limited to the CoWP film in the present invention; the barrier film 7 may also be formed by an electroless plating process using a cobalt alloy or a nickel alloy. Examples of the cobalt alloy include CoP, CoB, CoW, CoMo, CoWB, CoMoP, and CoMoB. Examples of the nickel alloy include NiWP, NiWB, NiMoP, and NiMoB. Further examples of the usable material include alloys containing both Co and Ni, and alloys containing both W and Mo. An addition of tungsten or molybdenum to cobalt or nickel increases the copper diffusion preventive effect. Also, phosphorus or boron auxiliarily added in the electroless plating causes the formed film of cobalt or nickel to have a fine crystal structure, thereby contributing to the copper diffusion preventive effect.

One example of the composition of the electroless plating liquid for use in the above-mentioned electroless plating and one example of a set of electroless plating conditions are given below.

(In the case of CoP)<

Composition of Electroless Plating Liquid>

Cobalt chloride: 10 to 100 g/l (cobalt sulfate or the like)

Glycine: 2 to 50 g/l (ammonium salt of citric acid, tartaric acid, succinic acid, malic acid, malonic acid, formic acid or the like, or a mixture thereof, or the like)

Ammonium hypophosphite: 2 to 200 g/l (formalin, glyoxylic acid, hydrazine, ammonium boron hydride, dimethylamineborane (DMAB), or the like)

Ammonium hydroxide (tetramethylammonium hydroxide (TMAH) or the like: pH regulator)

<Electroless Plating Conditions>

| | |
|---|---|
| Plating liquid temperature: | 50 to 95° C. |
| pH of plating liquid: | 7 to 12 |

When formalin, glyoxylic acid, hydrazine or the like is used in place of ammonium hypophosphite in the above electroless plating liquid composition, the resulting barrier film does not contain phosphorus (P). Besides, when dimethylamineborane (DMAB) or the like is used in place of ammonium boron hydride, the resulting film contains boron (B) in place of phosphorus (P). This applies also to the following electroless plating liquid composition. (In the cases of CoWP, CoMoP, NIWP, and NiMoP)

### Composition of Electroless Plating Liquid

Cobalt chloride or nickel chloride: 10 to 100 g/l (cobalt sulfate, nickel sulfate or the like)

Glycine: 2 to 50 g/l (ammonium salt of citric acid, tartaric acid, succinic acid, malic acid, malonic acid, formic acid or the like, or a mixture thereof, or the like)

Ammonium hypophosphite: 2 to 200 g/l (formalin, glyoxylic acid, hydrazine, ammonium boron hydride, dimethylamineborane (DMAB), or the like)

Ammonium hydroxide (tetremethylammonium hydroxide (TMAH) or the like: pH regulator)

<Electroless Plating Conditions>

| | |
|---|---|
| Plating liquid temperature: | 50 to 95° C. |
| pH of plating liquid: | 8 to 12 |

In the above electroless plating, like in the pretreatment, a film can be formed by a spin treatment using a spin coater, a paddle treating, a dipping treatment or the like.

By the above procedure it is possible to manufacture a high-quality semiconductor device, as shown in FIG. 1, which has an excellent electro-migration resistance together with a copper diffusion preventive function and in which RC delay is suppressed.

As has been described above, in the method of manufacturing a semiconductor device according to the present invention, the catalyst metal 10a is preliminarily contained in the metallic wiring, at the time of forming the Cu wiring 2. Specifically, in forming the Cu wiring 2 filling the groove by electroplating, the catalyst metal 10a is added to the electroplating liquid, and the Cu wiring 2 filling the groove is formed by electroplating using the electroplating liquid. Then, of the catalyst metal 10a contained in the Cu wiring 2, the catalyst metal 10a present at the surface of the Cu wiring 2 is used as nuclei of catalyst, namely, as a catalyst for starting an electroless plating reaction, and, under this condition, electroless plating is conducted to thereby form the barrier film 7 having the copper diffusion preventive function on the Cu wiring 2.

With the Cu wiring 2 formed by such a method, the catalyst metal 10a to be the catalyst for starting the electroless plating reaction is dispersed inside the Cu wiring 2 and at the surface of the Cu wiring 2, so that the formation of the Cu wiring 2 provides the same effect as that in the case of conducting a catalytically activating treatment in the conventional manufacturing method, and the catalytically activating treatment step indispensable to the conventional manufacturing method is unnecessitated. As a result, in the method of manufacturing a semiconductor device according to the present invention, it is possible to efficiently form the barrier film 7 by simplified manufacturing steps, and to manufacture a high-quality semiconductor device in which the diffusion of copper atoms into the inter-layer insulating film is securely prevented.

Besides, in the method of manufacturing a semiconductor device according to the present invention, the catalytically activating step is not conducted as above-described, so that the Cu wiring 2 is not etched at the time of forming the barrier film 7. Therefore, the problems which would cause malfunctions of the semiconductor device, such as a rise in wiring resistance and a worsening of electro-migration resistance due to etching of the Cu wiring 2, are obviated, and a high-quality semiconductor device can be manufactured.

Furthermore, since the catalytically activating step is not conducted in the method of manufacturing a semiconductor device according to the present invention, the adsorption or remaining of the catalyst metal onto the inter-layer insulating film 3 as in the conventional manufacturing method is obviated. As a result, formation of the barrier film 7 on the inter-layer insulating film is prevented, so that it is possible to enhance the selectivity of film formation at the time of forming the barrier film 7, and to manufacture a high-quality semiconductor device.

Incidentally, the above-described method of manufacturing a semiconductor device is applicable to both a groove wiring technology based on the Damascene process and a groove wiring technology based on the dual Damascene process.

Now, a specific manufacturing method based on the so-called dual Damascene process, in which the present invention is applied to a semiconductor device having a multilayer wiring, will be described below.

First, in the same manner as in the case of the monolayer wiring described above, a first wiring, namely, a lower-layer wiring as shown in FIG. 11 is formed. Next, a second wiring, namely, an upper-layer wiring is formed according to the following procedure. In the following description, the same members as those in the above description are denoted by the same symbols as used above, and detailed description thereof is omitted.

To form the upper-layer wiring, first, a hydrofluoric acid (HF) solution treatment for the purpose of removing the copper atoms remaining on an inter-layer insulating film 3 is conducted.

Next, as shown in FIG. 12, an inter-layer insulating film 10b consisting of SiOC corresponding to the depth of a via hole and an SiN film 11 for a copper diffusion preventive purpose are sequentially formed by a CVD process.

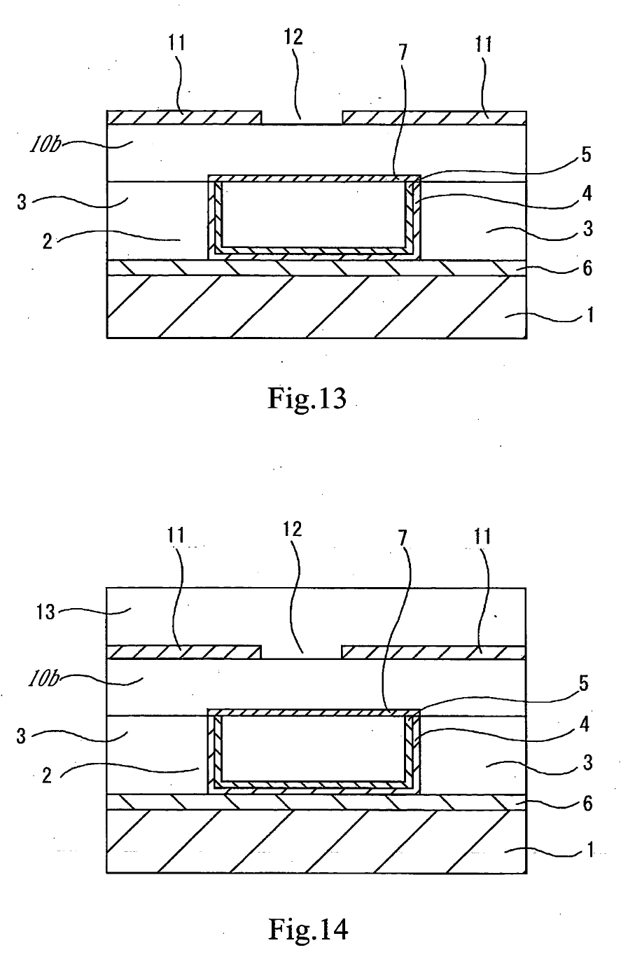

Subsequently, as shown in FIG. 13, the SiN film 11 is processed by photolithography followed by dry etching, to form an opening 12 in a pattern at a position which is directly above a lower-layer wiring 2 and which corresponds to the via hole.

Next, as shown in FIG. 14, SiOC is built up on the SiN film 11 inclusive of the opening 12 in an amount corresponding to the depth of an upper-layer wiring by a CVD process, to form an inter-layer insulating film 13.

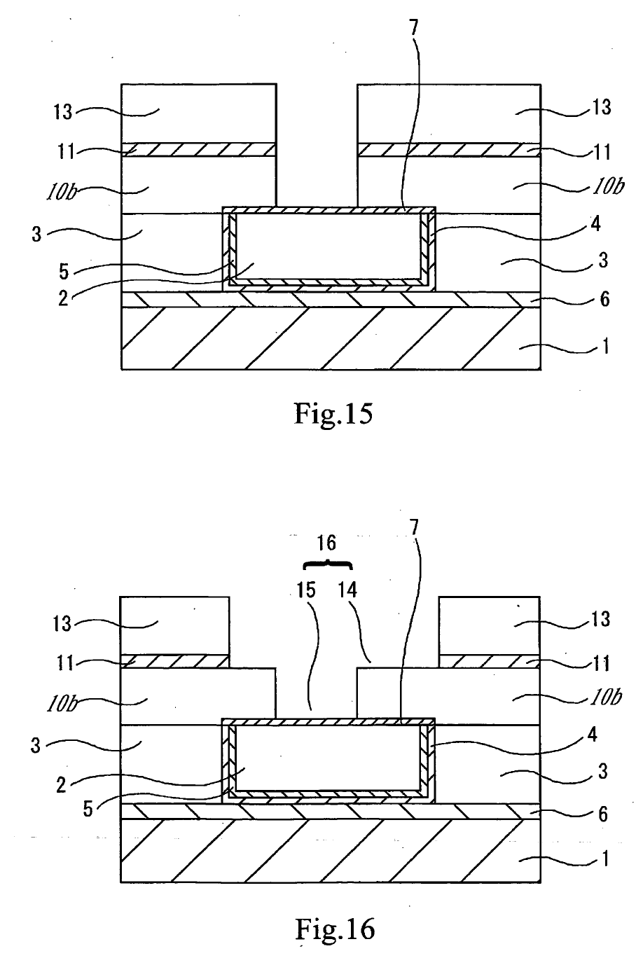

Subsequently, a resist is applied to the inter-layer insulating film 13, and resist mask (omitted in the figure) is formed by photolithography technique. Thereafter, the inter-layer insulating film 13 is processed by etching using the resist mask. The etching is made to proceed further, thereby processing the inter-layer insulating film 10b as shown in FIG. 15. This etching is stopped on the barrier film 7.

Next, a pattern of a resist (omitted in the figure) is again formed on portions other than the portion corresponding to the wiring shape by photolithography technique. Then, etching is conducted by use of the resist mask. When the resist is removed, as shown in FIG. 16, a via hole 15 communicated to the barrier film 7 and having the inter-layer insulating film 10b as side walls is formed in the inter-layer insulating film 10b, and an upper-layer wiring groove 14 having the inter-layer insulating film 13 and the SiN film 11 as side walls is formed in the inter-layer insulating film 13. Hereinafter the wiring groove 14 and the via hole 15 will be collectively referred to a recess 16.

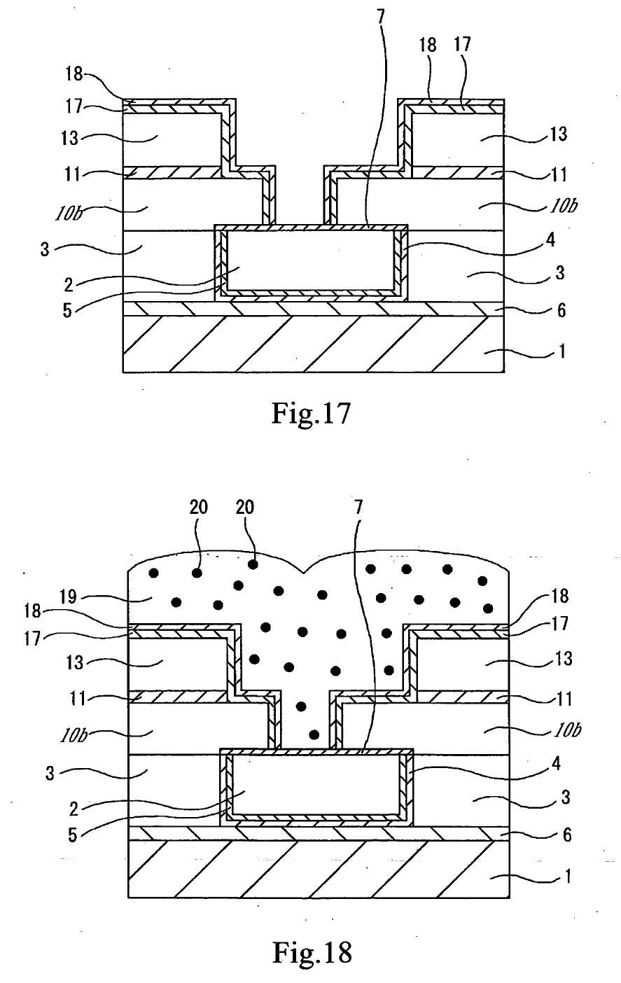

Subsequently, as shown in FIG. 17, a barrier metal film 17 consisting, for example, of TaN for preventing the diffusion of copper into the inter-layer insulating film 10b and the inter-layer insulating film 13 is formed by a PVD process, followed by formation of a Cu seed layer 18 by a PVD process. The material of the barrier metal film 17 is not limited to TaN; materials excellent in barrier property against Cu, such as Ta, TiN, and WN can be used. The Cu seed layer 18 serves as a conductive layer at the time of forming a film of Cu by electroplating in the subsequent Cu filling step. The method for forming the barrier metal film 17 and the Cu seed layer 18 is not limited to the PVD process; they may be formed by a CVD process. The film thicknesses depend on design rules, but it is preferable that the film thickness of the barrier film 17 is not more than 50 nm, and the film thickness of the Cu seed layer 18 is not more than 200 nm.

Next, as shown in FIG. 18, Cu electroplating is conducted to fill the recess 16 with Cu 19. In this case, in the same manner as described above, Pd as a catalyst metal 20 is preliminarily added to a Cu electroplating liquid used for the Cu electroplating. The catalyst metal 20 functions as a catalyst for starting an electroless plating reaction at the time of forming a barrier film 22 which will be described later. The film thickness of Cu 19 differs depending on the depth of the recess 16, but it is preferably not more than 2 μm by a standard.

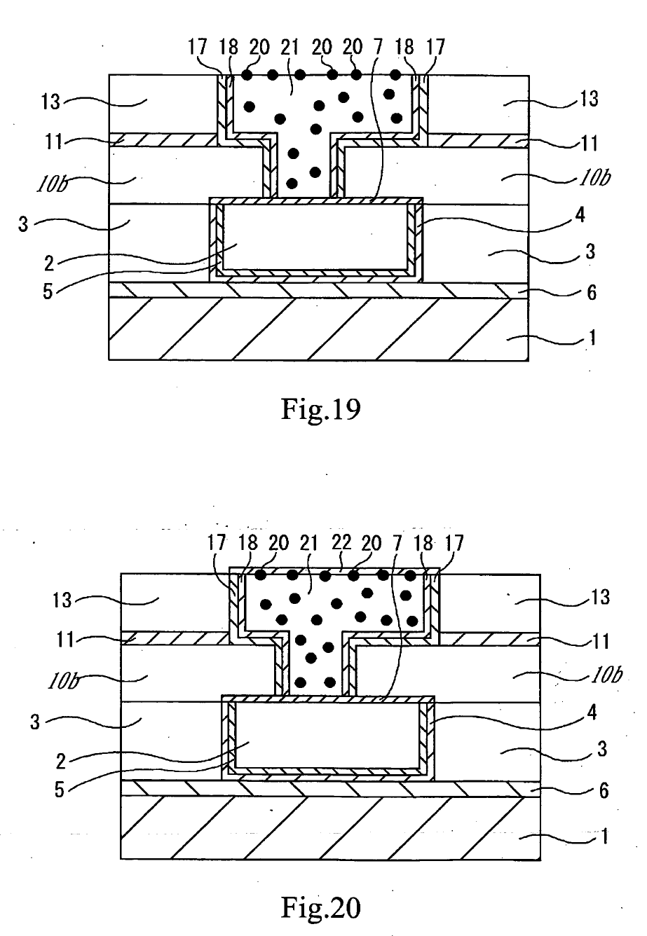

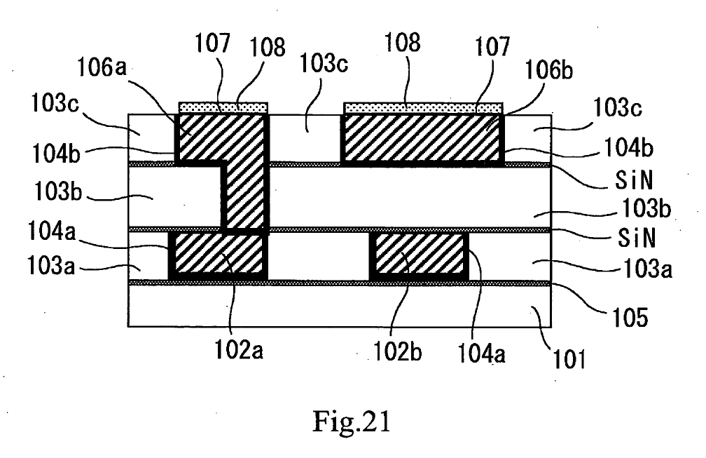

Subsequently, as shown in FIG. 19, surplus portions of Cu 19, the barrier metal film 17 and the Cu seed layer 18 are removed, leaving Cu 19 only in the recess 16, to form a Cu wiring 21 which is an upper-layer wiring. As a result, Pd contained in the Cu wiring 21 is exposed at the surface of the Cu wiring 21. Namely, the catalyst metal 20 which functions as a catalyst at the time of forming the barrier film 22 in the subsequent step is exposed at the surface of the Cu wiring 21.

For removal of surplus Cu 19, polishing by CMP in general use can be used. In this step, it is necessary to finish the polishing at the surface of the inter-layer insulating film 13 so as to leave Cu 19 as a wiring material only in the recess 16, and, further, it is preferable to control the polishing so that the wiring material is not left on the inter-layer insulating film 13. In the polishing step by CMP, the plurality of materials of Cu 19, the barrier metal film 17 and the Cu seed layer 18 must be polished away, so that it is necessary to control the polishing liquid (slurry), the polishing conditions and the like according to the materials to be polished. Therefore, a plurality of polishing steps may be needed in some cases.

Next, the barrier film 22 is formed on the Cu wiring 21. In this case, as required, a pretreatment for removing a spontaneous oxide film formed on the Cu wiring 21 after the polishing step by CMP is conducted, and thereafter the barrier film 22 is formed on the Cu wiring 21 by an electroless plating process. With the electroless plating process adopted, the barrier film 22 can be selectively formed only on the Cu wiring 21, so that a step of etching the barrier film 22 can be omitted. A specific example of the pretreatment process is given below.

<Pretreatment>

(1) Degreasing treatment: The wettability of the surface is enhanced by alkali degreasing or acid degreasing.

(2) Acid treatment: Neutralization with 2 to 3% hydrochloric acid or the like is conducted and, simultaneously, oxidized Cu at the surface is removed.

(3) Rinsing with Pure Water

Examples of the treating method in (1) degreasing treatment, and (2) acid treatment in the above-mentioned pretreatment include a spin treatment using a spin coater, a paddle treatment (liquid paddling), and a dipping treatment.

Subsequently, a CoWP film, for example, as the barrier film 22 is formed on the surface of the Cu wiring 21 by electroless plating. To form the CoWP film, a CoWP electroless plating reaction is started by using Pd, which is the catalyst metal 20, exposed at the surface of the Cu wiring 21 as a catalyst. Then, the electroless plating reaction is allowed to proceed under an autocatalytic action, whereby the CoWP film as the barrier film 22 can be formed on the Cu wiring 21 as shown in FIG. 20.

Here, as has been described above, Pd as the catalyst metal 20 is exposed only at the surface of the Cu wiring 21, and the electroless plating proceeds only where Pd is present. Therefore, it is possible to selectively form the barrier film 22 only on the Cu wiring 21.

Followingly, the same or similar process is repeated, whereby it is possible to produce a Cu multilayer wiring in which diffusion of copper is securely prevented and which is high in reliability.

While examples of the cases where the present invention is applied to a monolayer wiring and to a multilayer wiring have been described in the foregoing, the present invention is not limited to the above descriptions, and appropriate modifications are possible without departing from the gist of the present invention.

In addition, in forming a wiring in a multilayer structure, the formation of the wiring is not limited to the formation of the wiring by the dual Damascene process, and any method or process may be adopted.

### INDUSTRIAL APPLICABILITY

The method of manufacturing a semiconductor device according to the present invention is a method of manufacturing a semiconductor device including a barrier film having a copper diffusion preventive function and formed on a copper-containing metallic wiring, the method including the steps of: conducting electroplating by use of an electroplating liquid containing a catalyst metal added thereto so as thereby to form the metallic wiring containing the catalyst metal; and conducting electroless plating by use of the catalyst metal exposed at the surface of the metallic wiring as a catalyst so as thereby to form the barrier film having the copper diffusion preventive function on the metallic wiring.

In the method of manufacturing a semiconductor device according to the present invention as above-mentioned, the formation of the metallic wiring by the electroplating using the electroplating liquid containing the catalyst metal added thereto produces the same effect as that in the case of conducting a catalytically activating treatment in the conventional manufacturing method. In the present invention, therefore, the catalytically activating treatment step indispensable to the conventional manufacturing method is not necessitated, so that it is possible to efficiently form the barrier film by simplified manufacturing steps, and to manufacture at low cost a high-quality semiconductor device in which the diffusion of copper atoms into the inter-layer insulating film is securely prevented.

Besides, in the method of manufacturing a semiconductor device according to the present invention, the absence of the catalytically activating step ensures that the metallic wiring itself is not etched, and the problems which would cause malfunctions of the semiconductor device, such as a rise in wiring resistance and a worsening of electro-migration resistance due to etching of the metallic wiring, are obviated, so that it is possible to manufacture a high-quality semiconductor device.

Furthermore, since the catalytically activating step is not conducted in the method of manufacturing a semiconductor device according to the present invention, the adsorption or remaining of the catalyst metal onto the inter-layer insulating film as in the conventional manufacturing method is obviated, so that it is possible to enhance the selectivity of film formation at the time of forming the barrier film, and to manufacture a high-quality semiconductor device.

According to the present invention, therefore, it is possible to provide a semiconductor device which is suitable for enhancing the operating speed thereof and which is high in quality and reliability.

1. A method of manufacturing a semiconductor device comprising a barrier film having a copper diffusion preventive function and formed on a copper-containing metallic wiring, said method comprising the steps of:
conducting electroplating by use of an electroplating liquid containing a catalyst metal added thereto so as thereby to form said metallic wiring containing said catalyst metal; and
conducting electroless plating by use of said catalyst exposed at the surface of said metallic wiring as a catalyst so as thereby to form said barrier film having said copper diffusion preventive function on said metallic wiring.

2. The method of manufacturing a semiconductor device according to claim 1, wherein said catalyst metal is added to said electroplating liquid in a complexed form.

3. The method of manufacturing a semiconductor device according to claim 1, wherein said catalyst metal is one selected from the group consisting of Au, Pt, Pd, Ag, Ni, and Co.

4. The method of manufacturing a semiconductor device according to claim 1, wherein
said barrier film is comprised of a cobalt alloy or a nickel alloy.
